(19) United States
(12) Patent Application Publication
(10) Pub. No.: US 2025/0233025 A1
(43) Pub. Date: Jul. 17, 2025

(54) SUBSTRATE PROCESSING METHOD, SUBSTRATE PROCESSING APPARATUS AND ELECTRONIC DEVICE MANUFACTURED USING THE SUBSTRATE PROCESSING METHOD

(71) Applicant: SAMSUNG DISPLAY CO., LTD., YONGIN-SI (KR)

(72) Inventors: YONG-WOO KIM, YONGIN-SI (KR); DONGHYEON LEE, YONGIN-SI (KR); DONG-HUN KANG, YONGIN-SI (KR); BOO-KAN KI, YONGIN-SI (KR); HO YUN BYUN, YONGIN-SI (KR); JEONGIN LEE, YONGIN-SI (KR); SEONGSIK CHOI, YONGIN-SI (KR); JEONG-SEOP CHOI, YONGIN-SI (KR)

(21) Appl. No.: 18/999,003

(22) Filed: Dec. 23, 2024

(30) Foreign Application Priority Data
Jan. 17, 2024 (KR) 10-2024-0007340

(51) Int. Cl. H01L 21/66; H10K 59/80

(52) U.S. Cl. CPC H01L 22/12; H10K 59/873

(57) ABSTRACT

A substrate processing method includes placing a target substrate with a protection member attached to an upper surface of the target substrate on a stage, applying a first adsorption pressure having a first intensity between the stage and the target substrate and removing the protection member attached to the target substrate, applying a second adsorption pressure having a second intensity different from the first intensity between the stage and the target substrate, forming a preliminary adhesive layer by applying an ink on the target substrate, forming an adhesive layer by curing the preliminary adhesive layer formed on the target substrate, and inspecting a surface of the adhesive layer.

### CROSS-REFERENCE TO RELATED APPLICATION(S)

This application claims priority under 35 U.S.C. § 119 to Korean Patent Application No. 10-2024-0007340, filed on Jan. 17, 2024, the disclosure of which is incorporated by reference herein in its entirety.

### TECHNICAL FIELD

Embodiments of the present disclosure relate to a substrate processing method and a substrate processing apparatus, and more particularly, to a substrate processing method and a substrate processing apparatus for applying adsorption pressure to a target substrate.

### DISCUSSION OF RELATED ART

A display device is a device that displays images to provide visual information to users. A display device may include a plurality of layers and an adhesive layer that bonds the plurality of layers. The adhesive material forming the adhesive layer is ejected in a liquid form through an inkjet process and then cured through a curing process.

Before the adhesive material is ejected, a target substrate, which is an adhesive object, may be placed on a stage of the substrate processing device. After the target substrate is placed on the stage, the target substrate may be pressed to the stage using a pressure difference between the stage and the target substrate. The inkjet process of ejecting the adhesive material on the target substrate pressed through an inkjet processing module may be performed.

### SUMMARY

Embodiments of the present disclosure provide a substrate processing method for manufacturing a display device with increased display quality.

Embodiments of the present disclosure provide a substrate processing apparatus.

A substrate processing method according to an embodiment includes placing a target substrate with a protection member attached to an upper surface of the target substrate on a stage, applying a first adsorption pressure having a first intensity between the stage and the target substrate and removing the protection member attached to the target substrate, applying a second adsorption pressure having a second intensity different from the first intensity between the stage and the target substrate, forming a preliminary adhesive layer by applying an ink on the target substrate, forming an adhesive layer by curing the preliminary adhesive layer formed on the target substrate, and inspecting a surface of the adhesive layer.

In an embodiment, the first intensity of the first adsorption pressure is larger than the second intensity of the second adsorption pressure.

In an embodiment, the first intensity of the first adsorption pressure is about 75 kPa or less, and the second intensity of the second adsorption pressure is about 2 kPa or more to about 14 kPa or less

In an embodiment, inspecting the surface of the adhesive layer includes applying a third adsorption pressure having a third intensity between the stage and the target substrate.

In an embodiment, the third intensity of the third adsorption pressure is smaller than the first intensity of the first adsorption pressure.

In an embodiment, the third intensity of the third adsorption pressure is about 2 kPa or more to about 14 kPa or less.

In an embodiment, the third intensity of the third adsorption pressure is about equal to the second intensity of the second adsorption pressure.

In an embodiment, the third intensity of the third adsorption pressure is different from the second intensity of the second adsorption pressure.

In an embodiment, forming the preliminary adhesive layer includes maintaining the second adsorption pressure between the stage and the target substrate.

In an embodiment, after forming the preliminary adhesive layer, an adsorption pressure applied between the stage and the target substrate is about O kPa until the adhesive layer is formed.

In an embodiment, placing the target substrate on the stage includes forming a space between the target substrate and the stage, and removing the protection member includes removing the space by pressing the target substrate to the stage through the first adsorption pressure.

In an embodiment, inspecting the surface of the adhesive layer includes obtaining information about the surface of the adhesive layer and measuring a thickness of the adhesive layer.

In an embodiment, the ink includes an adhesive material.

In an embodiment, the ink includes an optically clear resin.

A substrate processing apparatus according to an embodiment includes a stage on which a target substrate is placed, a pressure generator configured to apply an adsorption pressure between the stage and the target substrate, a first pressure controller configured to adjust the adsorption pressure applied by the pressure generator to a first adsorption pressure having a first intensity, and a second pressure controller configured to adjust the adsorption pressure applied by the pressure generator to a second adsorption pressure having a second intensity different from the first intensity.

In an embodiment, the first intensity of the first adsorption pressure is larger than the second intensity of the second adsorption pressure.

In an embodiment, the first intensity of the first adsorption pressure is about 75 kPa or less, and the second intensity of the second adsorption pressure is about 14 kPa or less.

In an embodiment, the apparatus further includes an ink processing module configured to eject an ink onto the target substrate, a curing module configured to cure the ink by irradiating the ink with light, and a measurement module configured to measure a surface of the ink cured.

In an embodiment, the second pressure controller is configured to adjust an intensity of the adsorption pressure when the ink processing module operates.

In an embodiment, the second pressure controller is configured to adjust an intensity of the adsorption pressure when the measurement module operates.

In a substrate processing method according to embodiments of the present disclosure, a first adsorption pressure is applied to a target substrate to which a protection member is attached to a stage to remove the protection member, a second adsorption pressure different from the first adsorption pressure is applied, an ink is applied on the target substrate, and the ink is cured to form an adhesive layer. After the first adsorption pressure is applied between the target substrate and the stage, the second adsorption pressure, whose intensity is relatively smaller than an intensity of the first adsorption pressure, may be applied in a subsequent process. Accordingly, when a foreign substance is present on a surface of the stage, a thickness of the adhesive layer formed around the foreign substance is reduced, and the occurrence of stains generated in a display device including the adhesive layer may be reduced. Accordingly, a display quality of the display device may be increased.

In a substrate processing apparatus according to embodiments of the present disclosure, the substrate processing apparatus may include a stage on which the target substrate is placed, a pressure generator that generates an adsorption pressure between the stage and the target substrate, a first pressure generator that adjusts the adsorption pressure to the first adsorption pressure, and a second pressure generator that adjusts the adsorption pressure to the second adsorption pressure. Accordingly, while performing an inkjet process, a curing process, and the like during substrate processing, the substrate processing apparatus may adjust an intensity of the adsorption pressure to be relatively smaller than an intensity when the target substrate is pressed to the stage. Therefore, a display device with increased display quality may be manufactured through the substrate processing method using the substrate processing apparatus.

### BRIEF DESCRIPTION OF THE DRAWINGS

The above and other features of the present disclosure will become more apparent by describing in detail embodiments thereof with reference to the accompanying drawings.

FIG. 1 is a side view illustrating a substrate processing apparatus according to an embodiment of the present disclosure.

FIG. 2 is a block diagram illustrating a stage and pressure controllers of FIG. 1.

FIG. 3 is a block diagram illustrating a substrate processing method according to an embodiment of the present disclosure.

FIGS. 4, 5, 6, 7, 8, 9, 10, and 11 are views illustrating the substrate processing method of FIG. 3.

FIG. 12 is a cross-sectional view illustrating a manufactured display device according to the substrate processing method of FIG. 3.

FIG. 13 is an enlarged cross-sectional view illustrating an area A of FIG. 12.

FIG. 14 is a block diagram of an electronic device according to an embodiment of the present disclosure.

FIG. 15 is a schematic diagram of the electronic device according to various embodiments of the present disclosure.

### DETAILED DESCRIPTION OF THE EMBODIMENTS

Embodiments of the present disclosure will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

Spatially relative terms, such as “beneath”, “below”, “lower”, “under”, “above”, “upper”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below.

It will be understood that when a component such as a film, a region, a layer, etc., is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art. Further, it is to be understood that while parameters may be described herein as having “about” a certain value, according to embodiments, the parameter may be exactly the certain value or approximately the certain value within a measurement error as would be understood by a person having ordinary skill in the art. Other uses of these terms and similar terms to describe the relationships between components should be interpreted in a like fashion.

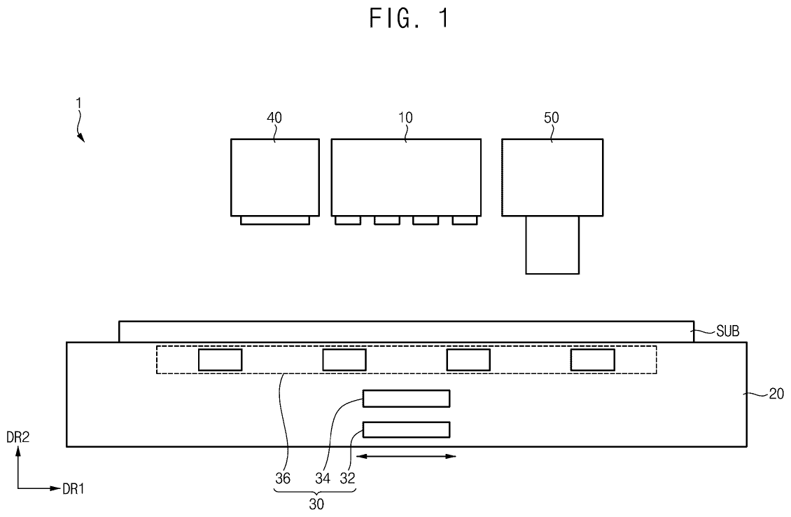

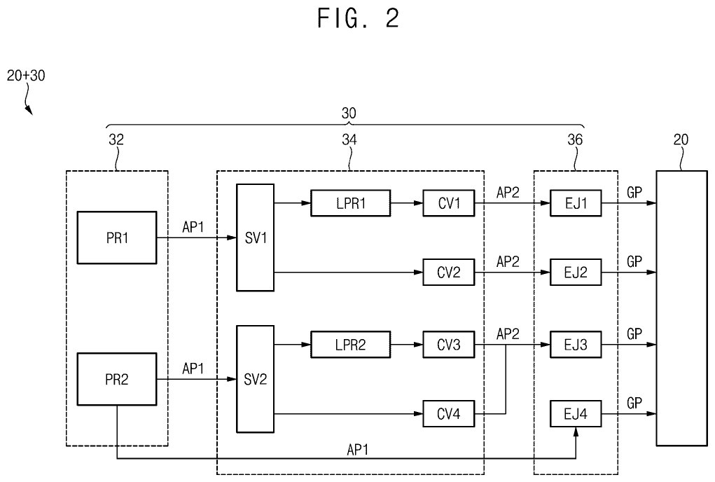

FIG. 1 is a side view illustrating a substrate processing apparatus according to an embodiment of the present disclosure. FIG. 2 is a block diagram illustrating a stage and pressure controllers of FIG. 1.

Referring to FIGS. 1 and 2, a substrate processing apparatus according to an embodiment of the present disclosure may include an inkjet processing module 10, a stage 20, an adsorption module 30, a curing module 40, and a measurement module 50.

The substrate processing apparatus 1 may be an apparatus that manufactures a display device including a plurality of layers using a target substrate SUB. In the substrate processing apparatus 1, the stage 20 and the adsorption module 30 may be components that fix the target substrate SUB before forming the plurality of layers. In the substrate processing apparatus 1, the inkjet processing module 10 and the curing module 40 may be apparatuses that form the plurality of layers on the target substrate SUB. In the substrate processing apparatus 1, the measurement module 50 may be an apparatus that measures surfaces of the plurality of layers.

The inkjet processing module 10 may include at least one inkjet head and at least one ink chamber. The inkjet head may eject an ink onto the target substrate SUB. The ink may be fully or partially applied to the target substrate SUB to form a structure having at least one layer. The structure formed by the ink may include a light-emitting layer or an adhesive layer. However, the structure formed by the ink is not limited thereto. The ink chamber may store the ink and supply the ink to the inkjet head according to an ejection signal.

The target substrate SUB may be placed on the stage 20. The stage 20 may be used for a process that manufactures the display device. For example, the stage 20 may be used for an inkjet process included in the process that manufactures the display device performed through the inkjet processing module 10. In addition, the stage 20 may be used for an ink curing process included in the process that manufactures the display device performed through the curing module 40. However, the present disclosure is not limited thereto, and the stage 20 may be used for various processes which utilize precise control included in the process manufacturing the display device.

The stage 20 may be moved to perform various processes together with the target substrate SUB. For example, the stage 20 may be moved in a first direction DR1 and/or in a second direction DR2 intersecting the first direction DR1 with the target substrate SUB through a transfer module included in the substrate processing apparatus 1. As the stage 20 may be moved through the transfer module with the target substrate SUB, the stage 20 and the target substrate SUB may pass through locations where the inkjet processing module 10, curing module 40, and measurement module 50 are each installed. Accordingly, the display device may be manufactured by performing various processes, such as the inkjet process and the curing process, on the target substrate SUB.

In an embodiment, the stage 20 may include an adsorption member capable of pressing the target substrate SUB. For example, the adsorption member may include an electrostatic chuck such as a ceramic chuck. However, the present disclosure is not limited thereto.

The adsorption module 30 may adjust a pressure between the stage 20 and the target substrate SUB. For example, the adsorption module 30 may generate an adsorption pressure GP between the target substrate SUB and the stage 20 so that the target substrate SUB is pressed against the stage 20. In an embodiment, the adsorption module 30 may automatically change the pressure between the stage 20 and the target substrate SUB at specific times while various processes are performed on the target substrate SUB. Alternatively, the adsorption module 30 may passively change the pressure between the stage 20 and the target substrate SUB according to a user's operation at specific times.

The adsorption module 30 may include a first pressure controller 32, a second pressure controller 34, and a pressure generator 36. The first pressure controller 32 may include a first pressure regulator PR1 and a second pressure regulator PR2 that control a pressure and/or a flow rate of air. The first pressure controller 32 may adjust the first pressure regulator PRI and the second pressure regulator PR2 so that a first adsorption pressure AP1 having a first intensity is applied between the target substrate SUB and the stage 20. The first adsorption pressure AP1 may be a pressure when the target substrate SUB is pressed against the stage 20 after the target substrate SUB is placed on the stage 20. However, in the present disclosure, the number of pressure regulators is not limited thereto.

The second pressure controller 34 may include a first low pressure regulator LPR1, a second low pressure regulator LPR2, a first sole valve SV1, a second sole valve SV2, and first, second, third, and fourth check valves CV1, CV2, CV3, and CV4 that control the pressure and/or flow rate of air. However, in the present disclosure, a number of sole valves, low pressure regulators, and check valves are not limited thereto.

The first sole valve SV1 and the second sole valve SV2 may include a solenoid and an orifice. The first sole valve SV1 and the second sole valve SV2 may control an inflow of an air delivered to the second pressure controller 34 by an electromagnetic induction. For example, the first sole valve SV1 and the second sole valve SV2 may introduce an air received from the first pressure controller 32 into the second pressure controller 34, and may selectively not introduce an air into the second pressure controller 34. Accordingly, the first sole valve SV1 and the second sole valve SV2 may be adjusted so that a second intensity of the second adsorption pressure AP2 may be about 0 kPa.

The first low pressure regulator LPR1 and the second low pressure regulator LPR2 may change a pressure of air introduced through the first sole valve SV1 and the second sole valve SV2. For example, the first low pressure regulator LPR1 and the second low pressure regulator LPR2 may adjust the second intensity of the second adsorption pressure AP2 to be lower than the first intensity of the first adsorption pressure AP1. For example, the first low pressure regulator LPR1 and the second low pressure regulator LPR2 may adjust an intensity so that the second intensity of the second adsorption pressure AP2 is more than about 0 kPa or more to about 75 kPa or less.

The first, second, third and fourth check valves CV1, CV2, CV3, and CV4 may release air having a second adsorption pressure AP2. In addition, the first, second, third, and fourth check valves CV1, CV2, CV3, and CV4 may control a flow of an air discharged from the second pressure controller 34, which may prevent air from flowing back.

For example, the second pressure controller 34 may adjust an intensity of the adsorption pressure GP to about 0 kPa through the first sole valve SV1 and the second sole valve SV2, and may adjust the intensity of the adsorption pressure GP to be lower than the first intensity through first low pressure regulator LPR1 and the second low pressure regulator LPR2.

In an embodiment, the first intensity of the first adsorption pressure AP1 may be about 75 kPa or less. In an embodiment, the second intensity of the second adsorption pressure AP2 may be about 14 kPa or less. For example, the second intensity of the second adsorption pressure AP2 may be about 2 kPa or more to about 14 kPa or less. For example, the second intensity of the second adsorption pressure AP2 may be about 2 kPa. The first adsorption pressure AP1 and the second adsorption pressure AP2 may be applied in a direction in which the target substrate SUB is coupled to the stage 20.

In an embodiment, the second pressure controller 34 may adjust an intensity of the adsorption pressure GP while the curing module 40 operates to be smaller than an intensity of the adsorption pressure GP while the inkjet processing module 10 operates. In addition, the second pressure controller 34 may adjust an intensity of the adsorption pressure GP while the curing module 40 operates to be smaller than an intensity of the adsorption pressure GP while the measurement module 50 operates. For example, an intensity of the adsorption pressure GP, while the curing module 40 operates is about 0 kPa, where no adsorption pressure is applied between the target substrate SUB and the stage 20, and an intensity of the adsorption pressure GP, while the inkjet processing module 10 and the measurement module 50 operates, may be about 2 kPa.

The pressure generator 36 may generate the adsorption pressure GP between the target substrate SUB and the stage 20. The pressure generator 36 may include first, second, third, and fourth ejectors EJ1, EJ2, EJ3, and EJ4 that generate the adsorption pressure GP. The first, second, and third ejectors EJ1, EJ2, EJ3 may receive air from the first pressure controller 32 and the second pressure controller 34, and the fourth ejector EJ4 may receive air from the first pressure controller 32. However, a number or role of ejectors in the present disclosure is not limited thereto.

The first to fourth ejectors EJ1, EJ2, EJ3, and EJ4 may adjust an intensity of pressure applied by an upper surface of the stage 20 to the target substrate SUB to a vacuum state. Accordingly, the adsorption pressure GP may be generated by the difference between an intensity of pressure applied by the upper surface of the stage 20 to the target substrate SUB and the intensity of an atmospheric pressure applied to a rear surface of the stage 20. For example, when a vacuum is maintained by the vacuum member between the target substrate SUB and the upper surface of the stage 20, a pressure difference generated due to the atmospheric pressure applied to the rear surface of the stage 20, and thus the adsorption pressure GP at which the target substrate SUB is pressed to the stage 20, may be generated.

The pressure generator 36 may generate the adsorption pressure GP in accordance with an air pressure input from the first pressure controller 32 and the second pressure controller 34. For example, if the pressure of the air input to the pressure generator 36 is the first adsorption pressure AP1, the adsorption pressure GP may be generated having an intensity about equal to the first intensity of the first adsorption pressure AP1 between the target substrate SUB and the stage 20. If the pressure of the air input to the pressure generator 36 is the second adsorption pressure AP2, the adsorption pressure GP having an intensity about equal to the second intensity of the second adsorption pressure AP2 between the target substrate SUB and the stage 20.

The curing module 40 may irradiate the ink applied to the target substrate SUB with a light by the inkjet processing module 10 to cure the ink. The curing process performed through the curing module 40 may include a pre-curing process. However, the present disclosure is not limited thereto, and the curing process may also include a main curing process performed after the pre-curing curing process. In addition, the light may be ultraviolet rays. However, the present disclosure is not limited thereto.

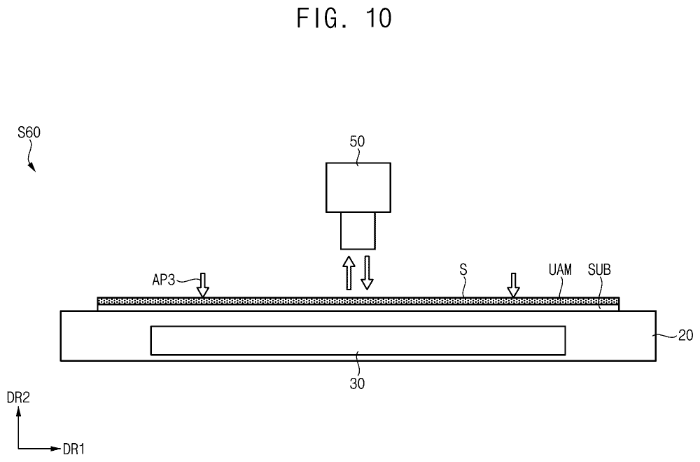

The measurement module 50 may measure a surface of the cured ink, which is described in more detail below with reference to FIG. 10.

As described above, the substrate processing apparatus 1 may include the stage 20 on which the target substrate SUB is placed, the pressure generator 36 that generates an adsorption pressure GP between the target substrate SUB and the stage 20, the first pressure controller 32 that adjusts the adsorption pressure to the first adsorption pressure AP1, and the second pressure controller 34 that adjusts the adsorption pressure to the second adsorption pressure AP2. Accordingly, while the substrate processing apparatus 1 performs the inkjet process and the curing process for substrate processing, the intensity of the adsorption pressure GP may be adjusted to the intensity (e.g., an intensity which is relatively smaller than the first adsorption pressure AP1 (e.g., the second adsorption pressure AP2)) when the target substrate is pressed to the stage.

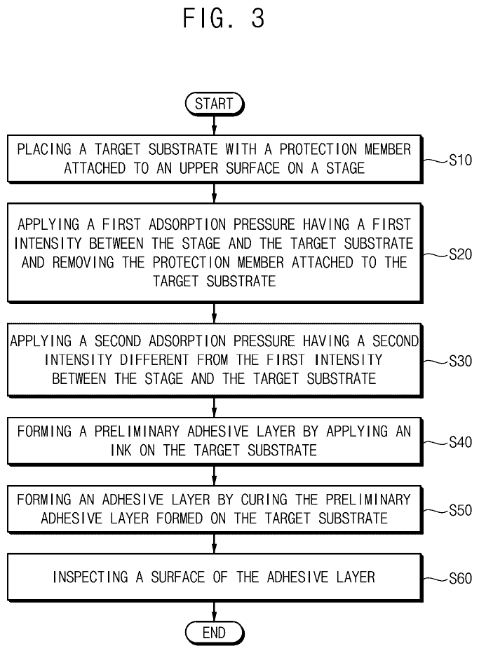

FIG. 3 is a block diagram illustrating a substrate processing method according to an embodiment of the present disclosure.

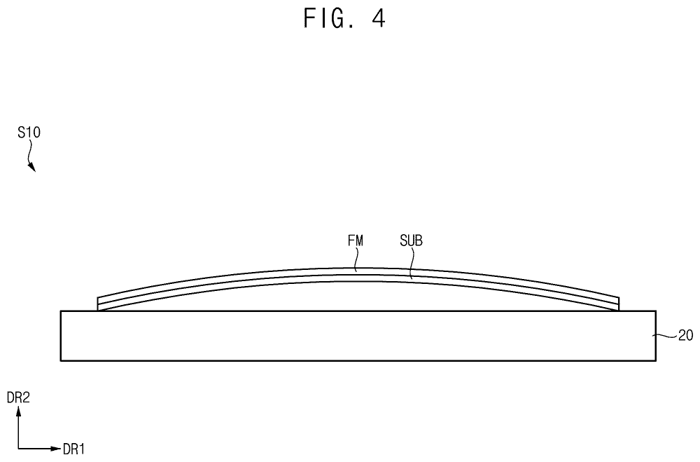

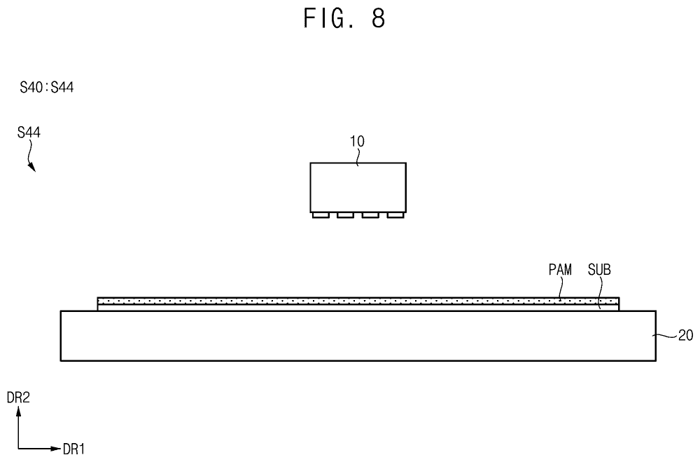

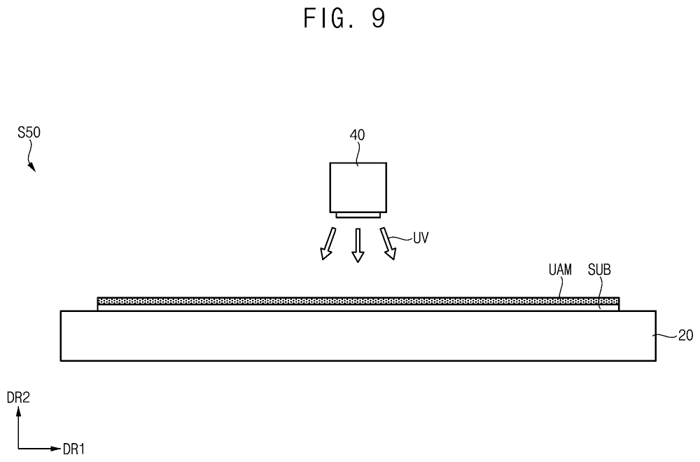

Referring to FIG. 3, a substrate processing method according to an embodiment of the present disclosure may include placing the target substrate (e.g., the target substrate SUB of FIG. 1) with a protection member (e.g., the protection member FM of FIG. 4) attached to an upper surface of the target substrate on the stage (the stage 20 of FIG. 1) S10, applying the first adsorption pressure (e.g., the first adsorption pressure AP1 of FIG. 2) having the first intensity between the stage and the target substrate and removing the protection member attached to the target substrate S20, applying the second adsorption pressure (e.g., the second adsorption pressure AP2 of FIG. 2) having the second intensity different from the first intensity between the stage and the target substrate S30, forming a preliminary adhesive layer (e.g., the preliminary adhesive layer PAM of FIG. 8) by applying an ink on the target substrate S40, forming an adhesive layer (e.g., adhesive layer UAM of FIG. 9) by curing the preliminary adhesive layer formed on the target substrate S50, and inspecting a surface (e.g., the surface S of FIG. 10) of the adhesive layer S60.

FIGS. 4, 5, 6, 7, 8, 9, 10, and 11 are views illustrating the substrate processing method of FIG. 3.

Components of the substrate processing apparatus used in the substrate processing method described with reference to FIGS. 4 to 11 (e.g., the inkjet processing module 10, the stage 20, the adsorption module 30, the curing module 40, and the measurement module 50) are substantially the same as the substrate processing apparatus 1 described with reference to FIGS. 1 and 2.

Hereinafter, for convenience of explanation, content that overlaps with the components of the substrate processing apparatus 1 described with reference to FIGS. 1 and 2 will be omitted or simplified.

FIG. 4 is a view for explaining the placing of the target substrate SUB with the protection member FM attached to the upper surface on the stage 20 in operation S10.

Referring to FIG. 4, the target substrate SUB to which the protection member FM is attached may be placed on the stage 20. Before the target substrate SUB is placed on the stage 20, the protection member FM may be attached to the upper surface of the target substrate SUB. The protection member FM may include, for example, a glass film, a polymer film, and the like, which may protect the target substrate SUB. However, the type of protection member FM used in the present disclosure is not limited thereto.

According to embodiments, the adsorption pressure (e.g., the adsorption pressure GP of FIG. 2) is not applied between the target substrate SUB and the stage 20. That is, the same atmospheric pressure may be applied between the target substrate SUB and the stage 20. Accordingly, in embodiments, the target substrate SUB is not pressed to the stage 20, and a space may be formed between the target substrate SUB and the stage 20.

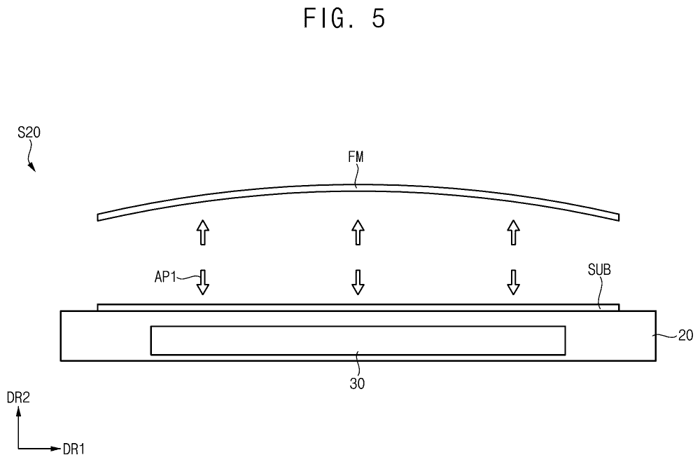

FIG. 5 is a view for explaining the applying of the first adsorption pressure AP1 having the first intensity between the stage 20 and the target substrate SUB and the removing of the protection member FM attached to the target substrate SUB in operation S20.

Referring to FIG. 5, the adsorption pressure (e.g., the adsorption pressure GP of FIG. 2) may be applied between the target substrate SUB and the stage 20. For example, the first adsorption pressure AP1 may be applied between the target substrate SUB and the stage 20 through the adsorption module 30. In an embodiment, the first intensity of the first adsorption pressure AP1 may be about 75 kPa. The target substrate SUB may be pressed to the stage 20 by the first adsorption pressure AP1. Accordingly, the space formed between the target substrate SUB and the stage 20 may be eliminated.

While the target substrate SUB is pressed against the stage 20, the protection member FM attached to the target substrate SUB may be removed. The protection member FM may be spaced apart in a direction opposite to a direction in which the target substrate SUB is pressed. For example, the target substrate SUB may be pressed in a direction opposite to the second direction DR2 toward the stage 20, and the protection member FM may be spaced apart from the target substrate SUB in the second direction DR2. The protection member FM may be removed from the target substrate SUB by a peeling apparatus included in the substrate processing apparatus of FIG. 1.

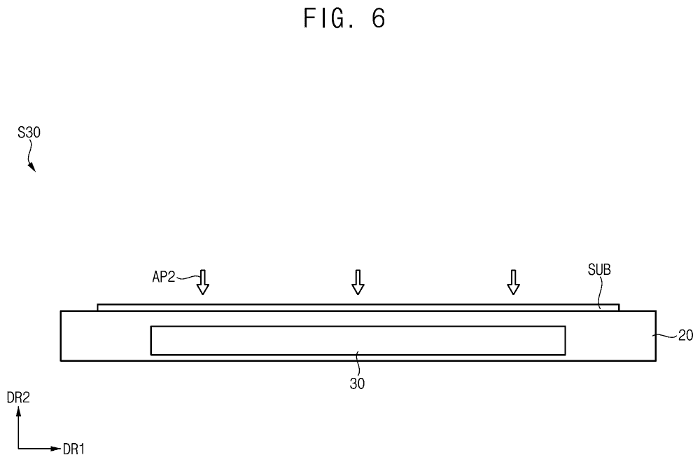

FIG. 6 is a view for explaining the applying of the second adsorption pressure AP2 having the second intensity different from the first intensity between the stage 20 and the target substrate SUB in operation S30.

Referring to FIG. 6, the adsorption module 30 may change the adsorption pressure between the stage 20 and the target substrate SUB from the first adsorption pressure AP1 to the second adsorption pressure AP2. For example, the first adsorption pressure AP1 may be changed to the second adsorption pressure AP2 through the second pressure controller 34 of FIG. 2. For example, the second adsorption pressure AP2 is applied between the stage 20 and the target substrate SUB through the first low pressure regulator LRP1 and the second low pressure regulator LRP2 of FIG. 2.

In an embodiment, the second intensity of the second adsorption pressure AP2 may be smaller than the first intensity of the first adsorption pressure AP1. For example, the second intensity of the second adsorption pressure AP2 may be about 14 kPa or less. For example, the second intensity of the second adsorption pressure AP2 may be about 2 kPa or more to about 14 kPa or less. For example, the second intensity of the second adsorption pressure AP2 may be about 2 kPa.

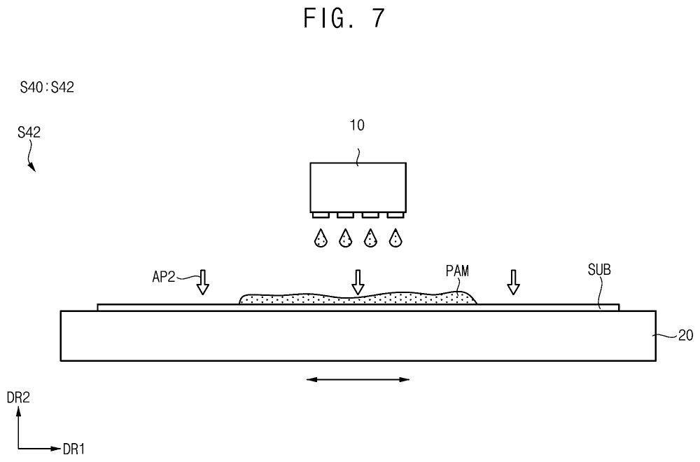

FIGS. 7 and 8 are views for explaining the forming of the preliminary adhesive layer PAM by applying the ink on the target substrate SUB in operation S40.

Referring to FIGS. 7 and 8, the forming of the preliminary adhesive layer PAM by applying the ink on the target substrate SUB S40 may include a first operation S42 of ejecting the ink onto the target substrate SUB, and a second operation S44 in which the first operation S42 is completed and the ink is entirely applied to the target substrate SUB, thereby ending an ejection of the ink from the inkjet processing module 10.

In the first operation S42, the stage 20 may move in the first direction DR1 to eject the ink entirely onto the target substrate SUB. However, in the present disclosure, the direction in which the stage 20 moves is not limited to the first direction DR1, and the stage 20 may move in any direction parallel to the stage 20.

In an embodiment, the ink may include an adhesive material. For example, the adhesive material may include an optically clear adhesive resin (OCR). However, the adhesive material of the present disclosure is not limited thereto.

In an embodiment, the second adsorption pressure AP2 may be maintained between the target substrate SUB and the stage 20 during the first operation S42. For example, the second adsorption pressure AP2 may be maintained between the target substrate SUB and the stage 20 until just before the second operation S44 is performed, which is when the ejection of the ink ends.

In an embodiment, the adsorption pressure is not applied between the target substrate SUB and the stage 20 when operation S44 begins. For example, an intensity of the adsorption pressure between the target substrate SUB and the stage 20 may be about 0 kPa. In operation S44, the second pressure controller 34 of FIG. 2 may operate. For example, in operation S44, the intensity of the adsorption pressure between the target substrate SUB and the stage 20 through the first sole valve SV1 and the second sole valve SV2 of FIG. 2 may be about 0 kPa.

FIG. 9 is a view illustrating the forming of the adhesive layer UAM by curing the preliminary adhesive layer (e.g., the preliminary adhesive layer PAM) formed on the target substrate in operation S50.

Referring to FIG. 9, after operation S44, the preliminary adhesive layer may be cured through the curing module 40. A curing process curing the preliminary adhesive layer may be a pre-curing process using ultraviolet rays. The adhesive layer UAM may be formed on the target substrate SUB by curing the preliminary adhesive layer. For example, the adhesive layer UAM may be a pre-cured adhesive layer.

According to embodiments, from operation S44 of FIG. 8 until the adhesive layer UAM is formed, the adsorption pressure is not applied between the target substrate SUB and the stage 20. For example, from operation S44 of FIG. 8 until the adhesive layer UAM is formed, an intensity of the adsorption pressure between the target substrate SUB and the stage 20 may be about 0 kPa. That is, from operation S44 of FIG. 8 until the adhesive layer UAM is formed, the first sole valve SV1 and the second sole valve SV2 of FIG. 2 may operate.

FIG. 10 is a view for explaining the inspecting of the surface of the adhesive layer UAM in operation S60.

Referring to FIG. 10, the surface S of the adhesive layer UAM may be measured through the measurement module 50. The measurement module 50 may obtain an image by irradiating a light onto the adhesive layer UAM and imaging the surface S of the adhesive layer UAM. Accordingly, the measurement module 50 may calculate a thickness at a specific point of the adhesive layer UAM. Using information about the thickness calculated by the measurement module 50, the user may determine whether a manufacturing of the display device has been appropriately performed. For example, the user may determine whether the cured ink is applied uniformly overall and whether the thickness is the same as a set value. If the user determines that the manufacturing of the display device was not properly performed, the inkjet process and curing process may be performed again.

While inspecting the surface S of the adhesive layer UAM, the adsorption module 30 may apply a third adsorption pressure AP3 between the target substrate SUB and the stage 20. In an embodiment, a third intensity of the third adsorption pressure AP3 may be smaller than the first intensity of the first adsorption pressure AP1. For example, the third intensity of the third adsorption pressure AP3 may be about 14 kPa or less. For example, the third intensity of the third adsorption pressure AP3 may be about 2 kPa or more to about 14 kPa or less. For example, the third intensity of the third adsorption pressure AP3 may be about 2 kPa.

The third adsorption pressure AP3, similar to the second adsorption pressure AP2, may be applied between the target substrate SUB and the stage 20 through the second pressure controller 34 of FIG. 2. For example, the third adsorption pressure AP3 may be applied between the target substrate SUB and the stage 20 through the first low pressure regulator LRP1 and the second low pressure regulator LRP2 of FIG. 2.

In an embodiment, the third intensity of the third adsorption pressure AP3 may be about equal to the second intensity of the second adsorption pressure AP2. For example, the second intensity of the second adsorption pressure AP2 may be about 2 kPa, and the third intensity of the third adsorption pressure AP3 may be about 2 kPa. Alternatively, the third intensity of the third adsorption pressure AP3 may be different from the second intensity of the second adsorption pressure AP2. For example, the second intensity of the second adsorption pressure AP2 may be about 2 kPa, and the third intensity of the third adsorption pressure AP3 may be about 1 kPa. However, the present disclosure is not limited thereto, and the second intensity of the second adsorption pressure AP2 and the third intensity of the third adsorption pressure AP3 may vary within an intensity range smaller than the first intensity of the first adsorption pressure AP1.

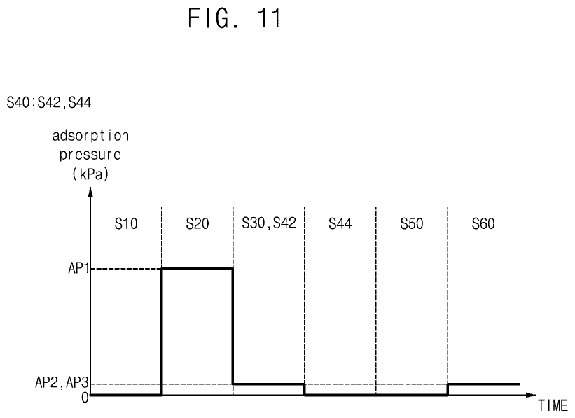

Referring to FIG. 11, in each operation included in the substrate processing method of FIG. 3, an adsorption pressure applied between the target substrate (e.g., the target substrate SUB of FIG. 1) and the stage (e.g., the stage 20 of FIG. 1) may vary.

Referring further to FIGS. 4, 5, 6, 7, 8, 9, and 10, according to embodiments, the adsorption pressure is not applied between the target substrate SUB and the stage 20, but the first adsorption pressure AP1 may be applied. For example, according to embodiments, in the placing of the target substrate SUB on the stage 20 in operation S10, the adsorption pressure is not applied between the target substrate SUB and the stage 20. After the target substrate SUB is placed, in the removing of the protection member FM from the target substrate SUB S20, the first adsorption pressure AP1 is applied between the target substrate SUB and the stage 20 to remove the protection member FM. The first adsorption pressure AP1 may have the highest intensity among the adsorption pressures applied in each operation included in the substrate processing method of FIG. 3.

After the first adsorption pressure AP1 is applied, the second adsorption pressure AP2 may be applied. For example, while changing from the first adsorption pressure AP1 to the second adsorption pressure AP2 through the second pressure controller 34 of FIG. 2 included in the adsorption module 30, the adsorption pressure applied between the target substrate SUB and the stage 20 may be reduced.

After the second adsorption pressure AP2 is applied, the inkjet processing module 10 may operate to eject the ink onto the target substrate SUB. While the ejecting of the ink onto the target substrate SUB S42 is performed, the second adsorption AP2 applied between the target substrate SUB and the stage 20 may be maintained.

When the inkjet processing module 10 determines that the ink ejection is complete and starts operation S44 in which the ink ejection operation is stopped, no adsorption pressure is applied between the target substrate SUB and the stage 20. A state in which the adsorption pressure is not applied may be maintained until the forming of the adhesive layer UAM by curing the preliminary adhesive layer PAM formed on the target substrate SUB in operation S50.

After the adhesive layer UAM is formed, the third adsorption pressure AP3 may be applied between the target substrate SUB and the stage 20 in the inspecting of the surface S of the adhesive layer UAM in operation S60. As described above, in an embodiment, the third intensity of the third adsorption pressure AP3 may be less than the first intensity of the first adsorption pressure AP1, and may be about equal to the second intensity of the second adsorption pressure AP2. Alternatively, the third intensity of the third adsorption pressure AP3 may be smaller than the first intensity of the first adsorption pressure AP1 and different from the second intensity of the second adsorption pressure AP2.

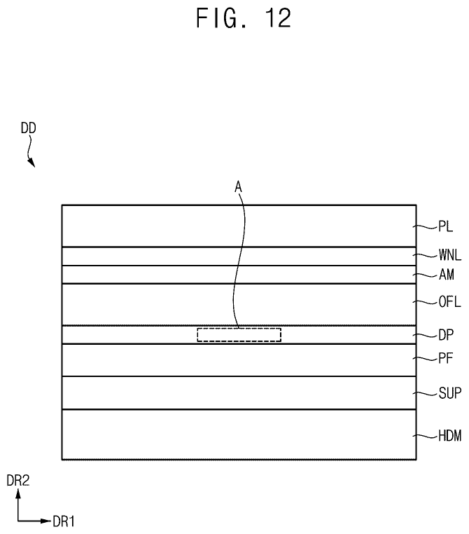

In embodiments of the present disclosure, since the adsorption module 30 includes the second pressure controller 34, after the first adsorption pressure AP1 is applied between the target substrate SUB and the stage 20, the second adsorption pressure AP2 and the third adsorption pressure AP3 having intensities that are relatively smaller than the first intensity of the adsorption pressure AP1 may be applied in the subsequent process. Accordingly, when a foreign substance is present on the surface of the stage 20, a thickness of the adhesive layer UAM formed around the foreign material may be reduced, thereby reducing the occurrence of a stain(s) generated in a display device including the adhesive layer. Accordingly, the display quality of a display device DD of FIG. 12 may be increased.

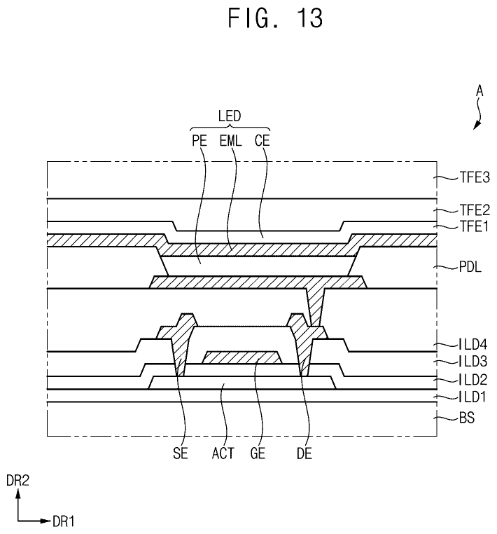

FIG. 12 is a cross-sectional view illustrating a manufactured display device according to the substrate processing method of FIG. 3. FIG. 13 is an enlarged cross-sectional view illustrating an area A of FIG. 12.

Referring to FIGS. 12 and 13, the display device DD may be manufactured through the substrate processing method of FIG. 3.

The display device DD may include a display panel DP, an optical functional layer OFL, a window layer WNL, a protection layer PL, a support member SUP, and a heat dissipation member HDM.

The display panel DP may include a base substrate BS, a first insulation layer ILD1, an active layer ACT, a second insulation layer ILD2, a gate electrode GE, a third insulation layer ILD3, a source electrode SE, a drain electrode DE, a fourth insulation layer ILD4, a pixel electrode PE, a pixel definition layer PDL, a light-emitting layer EML, a common electrode CE, a first encapsulation layer TFE1, a second encapsulation layer TFE2, and a third encapsulation layer TFE3.

The base substrate BS may be a transparent insulating substrate. For example, the base substrate BS may include a glass, a quartz, a plastic, and the like, used in alone or in combination with each other.

The first insulation layer ILD1 may be disposed on the base substrate BS. The first insulation layer ILD1 may prevent impurities from diffusing from the base substrate BS to the active layer ACT. The first insulation layer ILD1 may include an inorganic insulating material.

The active layer ACT may be disposed on the first insulation layer ILD1. The active layer ACT may include, for example, an amorphous silicon, a polycrystalline silicon, or an oxide semiconductor. The active layer ACT may include a source region, a drain region, and a channel region disposed between the source region and the drain region.

The second insulation layer ILD2 may be disposed on the first insulation layer ILD1. The second insulation layer ILD2 may cover the active layer ACT on the first insulation layer ILD1. For example, the second insulation layer ILD2 may have a uniform thickness along a profile of the active layer ACT. Alternatively, the second insulation layer ILD2 may cover the active layer ACT sufficiently, and may have a flat upper surface without creating a step around the active layer ACT. The second insulation layer ILD2 may include an inorganic insulating material.

The gate electrode GE may be disposed on the second insulation layer ILD2. The gate electrode GE may overlap the channel region of the active layer ACT. The gate electrode may include, for example, a metal, an alloy, a conductive metal oxide, a transparent metal nitride, a transparent material, and the like.

The third insulation layer ILD3 may be disposed on the second insulation layer ILD2. The third insulation layer ILD3 may cover the gate electrode GE on the second insulation layer ILD2. For example, the third insulation layer ILD3 may have a uniform thickness along a profile of the gate electrode GE. Alternatively, the third insulation layer ILD3 may cover the gate electrode GE sufficiently, and may have a flat upper surface without creating a step around the gate electrode GE.

The source electrode SE and the drain electrode DE may be disposed on the third insulation layer ILD3. The source electrode SE and the drain electrode DE may contact the active layer ACT through a contact hole penetrating the second insulation layer ILD2 and the third insulation layer ILD3. Each of the source electrode SE and drain electrode DE may include, for example, a metal, an alloy, a conductive metal oxide, a conductive metal nitride, a transparent conductive material, and the like. The active layer ACT, the gate electrode GE, the source electrode SE, and the drain electrode DE may form a transistor.

The fourth insulation layer ILD4 may be disposed on the third insulation layer ILD3. The fourth insulation layer ILD4 may have a substantially flat upper surface. The fourth insulation layer ILD4 may include an organic insulating material such as a polyimide PI. In an embodiment, an opening exposing a portion of the top surface of the drain electrode DE may be defined in the fourth insulation layer ILD4. In an embodiment, an opening that exposes a portion of the top surface of the source electrode SE may be defined in the fourth insulation layer ILD4.

The pixel electrode PE may be disposed on the fourth insulation layer ILD4. In an embodiment, the pixel electrode PE may contact the drain electrode DE through the opening. In an embodiment, the pixel electrode PE may contact the source electrode SE through the opening. The pixel electrode PE may include, for example, a metal, an alloy, a conductive metal oxide, a conductive metal nitride, a transparent conductive material, and the like.

The pixel definition layer PDL may be disposed on the fourth insulation layer ILD4. The pixel definition layer PDL may partially cover the pixel electrode PE. Additionally, an opening that exposes at least a portion of the pixel electrode PE may be defined in the pixel definition layer PDL. For example, the opening of the pixel definition layer PDL may expose a central portion of the pixel electrode PE, and the pixel definition layer PDL may cover edges of the pixel electrode PE. The pixel definition layer PDL may include a same material as the fourth insulation layer ILD4.

The light-emitting layer EML may be disposed on the pixel definition layer PDL. The light-emitting layer EML may be disposed on the pixel electrode PE exposed by the opening of the pixel definition layer PDL. The light-emitting layer EML may include an organic light emitting material. The organic light emitting material may include a low molecular weight organic compound or a high molecular weight organic compound. However, the present disclosure is not limited thereto, and the light-emitting layer EML may include materials such as, for example, quantum dots.

The common electrode CE may be disposed on the light-emitting layer EML. The common electrode CE may include, for example, a metal, an alloy, a conductive metal oxide, a conductive metal nitride, a transparent conductive material, and the like. The pixel electrode PE, the light-emitting layer EML, and the common electrode CE may form a light-emitting element LED.

The first encapsulation layer TFE1 may be disposed on the common electrode CE. The first encapsulation layer TFE1 may cover the light-emitting element LED. The first encapsulation layer TFE1 may have a substantially uniform thickness along the profile of the common electrode CE.

The second encapsulation layer TFE2 may be disposed on the first encapsulation layer TFE1. According to embodiments, the second encapsulation layer TFE2 does not create a step around the first encapsulation layer TFE1 and may have a substantially flat upper surface.

The third encapsulation layer TFE3 may be disposed on the second encapsulation layer TFE2. The third encapsulation layer TFE3 may have a substantially uniform thickness and a substantially flat upper surface. The first, second, and third encapsulation layers TFE1, TFE2, and TFE3 may seal the display area DA and protect the light-emitting element LED from external impurities.

The optical functional layer OFL may be disposed on the display panel DP. The optical functional layer OFL may be a polarizing layer that polarizes a light incident on the display panel DP from outside of the display panel DP. The polarizing layer may be stretched in one direction. A stretched direction of the polarizing layer may be an absorption axis, and a direction perpendicular to the stretched direction may be a transmission axis. However, the present disclosure is not limited thereto, and the optical functional layer OFL may be of other components that perform optical functions, such as, for example, a color filter, in addition to the polarizing layer.

The window layer WNL may be disposed on the optical functional layer OFL. The window layer WNL may be, for example, an ultrathin glass (UTG). However, the window layer WNL of the present disclosure is not limited thereto, and may include various materials such as a plastic.

The adhesive layer AM may be disposed between the window layer WNL and the optical functional layer OFL. For example, the adhesive layer AM may bond the window layer WNL and the optical functional layer OFL. In an embodiment, the adhesive layer AM may include an optically clear adhesive resin (OCR). However, the present disclosure is not limited thereto.

The protection layer PL may be disposed on the window layer WNL. The protection layer PL may protect the window layer WNL from an external shock. The protection layer PL may absorb a shock applied to the window layer WNL or prevent fingerprints and scratches from being created on the window layer WNL.

The protection film PF may be disposed under the display panel DP. The protection film PF may include a polymer material. For example, the polymer material may include a polyimide (PI), a polyethylene terephthalate (PET), a polycarbonate (PC), a polysulfone (PSF), polymethyl methacrylate (PMMA), etc. These can be used alone or in combination with each other.

The support member SUP may be disposed under the protection film PF. The support member SUP may support other components (e.g., the protection film PF, the display panel DP, and the like) at a lower portion of the display device DD. The support member SUP may include, for example, a metal, a glass, and the like.

The heat dissipation member HDM may be disposed under the support member SUP. The heat dissipation member HDM may include at least one heat dissipation layer. The heat dissipation member HDM may include, for example, a graphite, a carbon nanotube, a metal material, and the like.

The ink applied through the substrate processing method of FIG. 3 may form an adhesive layer AM. For example, the ink applied in FIG. 7 may be pre-cured to form the adhesive layer UAM of FIG. 9, and the adhesive layer UAM of FIG. 9 may be fully cured to form the adhesive layer AM. In addition, the target substrate SUB of FIG. 1 may be an optical functional layer OFL, a window layer WNL, or a display panel DP. However, the present disclosure is not limited thereto.

The display device according to the embodiment may be applied to various electronic devices. An electronic device according to an embodiment of the present disclosure may include the display device (e.g., the display device DD of FIG. 12) described above, and may further include modules or devices having additional functions in addition to the display device.

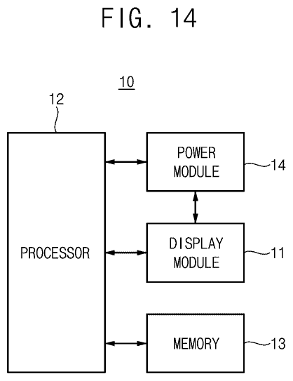

FIG. 14 is a block diagram of an electronic device according to an embodiment of the present disclosure.

Referring to FIG. 14, an electronic device 10 according to an embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for the operation of the processor 12 or the display module 11. When the processor 12 executes an application stored in the memory 15, an image data signal and/or an input control signal may be transmitted to the display module 11, and the display module 11 may process a signal received and output image information through a display screen.

The power module 14 may include a power supply module such as a power adapter or a battery device, and a power conversion module that converts the power supplied by the power supply module to generate power necessary for the operation of the electronic device 10.

At least one of the components of the electronic device 10 described above may be included in the display device (e.g., the display device DD of FIG. 12) according to the embodiments described above. In addition, a part among the individual modules functionally included in one module may be included in the display device, and another part may be provided separately from the display device. For example, the display device may include the display module 11, and the processor 12, the memory 13, and the power module 14 may be provided in the form of other devices within the electronic device 10 except for the display device.

In an embodiment, the display module 11 included in the display device may drive based on the image data signal and the input control signal received from the processor 12.

In an embodiment, the electronic device 10 may be manufactured using the substrate processing method of FIG. 3. For example, the electronic device 10 may include the display device manufactured by the substrate processing method.

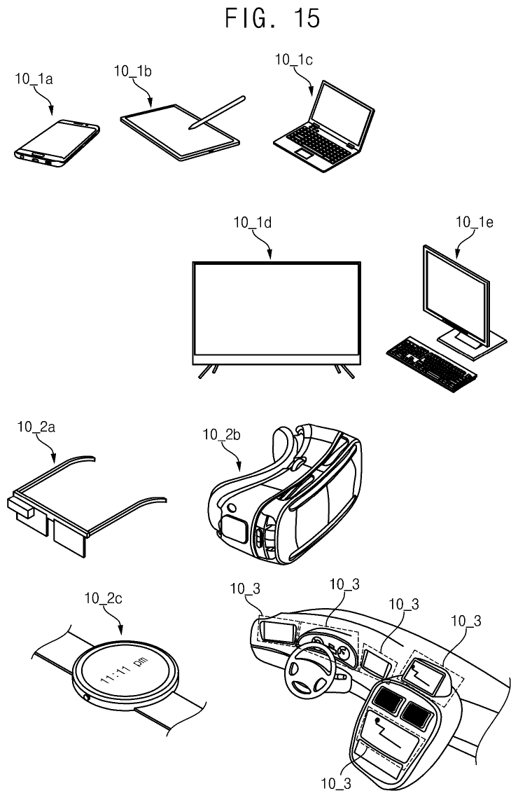

FIG. 15 is a schematic diagram of the electronic device according to various embodiments.

Referring to FIG. 15, various electronic devices to which display devices according to embodiments are applied may include not only image display electronic devices such as a smart phone 10_1a, a tablet PC 10_1b, a laptop 10_1c, a TV 10_1d, and a desk monitor 10_1e, but also a wearable electronic device including display modules such as smart glasses 10_2a, a head mounted display 10_2b, and a smart watch 10_2c, and a vehicle electronic device 10_3 including a dashboard, a center fascia, and display modules such as a CID (Center Information Display) and a room mirror display disposed in the dashboard.

The method and the apparatus according to embodiments of the present disclosure may be applied to manufacture a display device included in, for example, a computer, a notebook, a mobile phone, a smartphone, a smart pad, a PMP, a PDA, an MP3 player, or the like.

As is traditional in the field of the present disclosure, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, etc., which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A substrate processing method, comprising:
placing a target substrate with a protection member attached to an upper surface of the target substrate on a stage;
applying a first adsorption pressure having a first intensity between the stage and the target substrate and removing the protection member attached to the target substrate;
applying a second adsorption pressure having a second intensity different from the first intensity between the stage and the target substrate;
forming a preliminary adhesive layer by applying an ink on the target substrate;
forming an adhesive layer by curing the preliminary adhesive layer formed on the target substrate; and
inspecting a surface of the adhesive layer.

2. The substrate processing method of claim 1, wherein the first intensity of the first adsorption pressure is larger than the second intensity of the second adsorption pressure.

3. The substrate processing method of claim 2, wherein the first intensity of the first adsorption pressure is about 75 kPa or less, and
the second intensity of the second adsorption pressure is about 2 kPa or more to about 14 kPa or less.

4. The substrate processing method of claim 1, wherein inspecting the surface of the adhesive layer comprises applying a third adsorption pressure having a third intensity between the stage and the target substrate.

5. The substrate processing method of claim 4, wherein the third intensity of the third adsorption pressure is smaller than the first intensity of the first adsorption pressure.

6. The substrate processing method of claim 4, wherein the third intensity of the third adsorption pressure is about 2 kPa or more to about 14 kPa or less.

7. The substrate processing method of claim 4, wherein the third intensity of the third adsorption pressure is about equal to the second intensity of the second adsorption pressure.

8. The substrate processing method of claim 4, wherein the third intensity of the third adsorption pressure is different from the second intensity of the second adsorption pressure.

9. The substrate processing method of claim 1, wherein forming the preliminary adhesive layer comprises maintaining the second adsorption pressure between the stage and the target substrate.

10. The substrate processing method of claim 9, wherein after forming the preliminary adhesive layer, an adsorption pressure applied between the stage and the target substrate is about 0 kPa until the adhesive layer is formed.

11. The substrate processing method of claim 1, wherein placing the target substrate on the stage comprises forming a space between the target substrate and the stage, and
wherein removing the protection member comprises removing the space by pressing the target substrate to the stage through the first adsorption pressure.

12. The substrate processing method of claim 1, wherein inspecting the surface of the adhesive layer comprises obtaining information about the surface of the adhesive layer and measuring a thickness of the adhesive layer.

13. The substrate processing method of claim 1, wherein the ink includes an adhesive material.

14. The substrate processing method of claim 13, wherein the ink includes an optically clear resin.

15. A substrate processing apparatus, comprising:
a stage on which a target substrate is placed;
a pressure generator configured to apply an adsorption pressure between the stage and the target substrate;
a first pressure controller configured to adjust the adsorption pressure applied by the pressure generator to a first adsorption pressure having a first intensity; and
a second pressure controller configured to adjust the adsorption pressure applied by the pressure generator to a second adsorption pressure having a second intensity different from the first intensity.

16. The substrate processing apparatus of claim 15, wherein the first intensity of the first adsorption pressure is larger than the second intensity of the second adsorption pressure.

17. The substrate processing apparatus of claim 16, wherein the first intensity of the first adsorption pressure is about 75 kPa or less, and
the second intensity of the second adsorption pressure is about 14 kPa or less.

18. The substrate processing apparatus of claim 15, further comprising:
an ink processing module configured to eject an ink onto the target substrate;
a curing module configured to cure the ink by irradiating the ink with light; and
a measurement module configured to measure a surface of the ink cured.

19. The substrate processing apparatus of claim 18, wherein the second pressure controller is configured to adjust an intensity of the adsorption pressure when the ink processing module operates.

20. The substrate processing apparatus of claim 18, wherein the second pressure controller is configured to adjust an intensity of the adsorption pressure when the measurement module operates.

21. An electronic device comprising:
a processor configured to output an image data signal and an input control signal; and
a display device configured to drive based on the image data signal and the input control signal,
wherein the display device is manufactured by a substrate processing method, and
the substrate processing method comprising:
placing a target substrate with a protection member attached to an upper surface of the target substrate on a stage;
applying a first adsorption pressure having a first intensity between the stage and the target substrate and removing the protection member attached to the target substrate;
applying a second adsorption pressure having a second intensity different from the first intensity between the stage and the target substrate;
forming a preliminary adhesive layer by applying an ink on the target substrate;
forming an adhesive layer by curing the preliminary adhesive layer formed on the target substrate; and
inspecting a surface of the adhesive layer.
